(19) United States
(12) Patent Application Publication
(10) Pub. No.: US 2026/0052626 A1
(43) Pub. Date: Feb. 19, 2026

(54) MULTILAYER SUBSTRATE, CABLE, AND ELECTRONIC APPARATUS

(71) Applicant: Murata Manufacturing Co., Ltd., Nagaokakyo-shi (JP)

(72) Inventors: Ippei HATSUDA, Nagaokakyo-shi (JP); Noriaki OKUDA, Nagaokakyo-shi (JP); Masahiro KUROKAWA, Nagaokakyo-shi (JP)

(21) Appl. No.: 19/366,814

(22) Filed: Oct. 23, 2025

Related U.S. Application Data
(63) Continuation of application No. PCT/JP2024/013941, filed on Apr. 4, 2024.

(30) Foreign Application Priority Data
Jun. 13, 2023 (JP) 2023-096857

(51) Int. Cl. H05K 1/02; H05K 1/03; H05K 1/18

(52) U.S. Cl. CPC H05K 1/028; H05K 1/0313; H05K 1/181; H05K 1/189; H05K 2201/0129; H05K 2201/093; H05K 2201/10189

(57) ABSTRACT

A multilayer substrate includes a multilayer body including an insulator layer and a conductor layer that are stacked. The multilayer body includes a bent portion and a bent-portion continuation portion continuous with the bent portion. The multilayer body includes, in a portion of the bent portion, a protrusion protruding toward an inside of a bend of the bent portion.

### CROSS REFERENCE TO RELATED APPLICATIONS

This application claims the benefit of priority to Japanese Patent Application No. 2023-096857 filed on Jun. 13, 2023 and is a Continuation Application of PCT Application No. PCT/JP2024/013941 filed on Apr. 4, 2024. The entire contents of each application are hereby incorporated herein by reference.

### BACKGROUND OF THE INVENTION

### 1. Field of the Invention

The present invention relates to multilayer substrates, cables each including a multilayer substrate, and electronic apparatuses each including a multilayer substrate.

### 2. Description of the Related Art

A flexible substrate that is bent at a predetermined position is disclosed, for example, in International Publication No. 2014/109135. The flexible substrate described in International Publication No. 2014/109135 includes a first sheet portion that has a first main surface, a second sheet portion that is formed at a different position in a normal direction to the first main surface with respect to the first main surface and that has a second main surface, a plurality of bent sheet portions each of which connects end portions of the first and second sheet portions to each other, each of which has a main surface that is not parallel to the first and second main surfaces, and whose positions in a direction perpendicular to the normal direction differ from each other, a plurality of signal lines each of which is provided to pass through the first sheet portion and the second sheet portion and that are provided in such a way as to pass through different bent sheet portions in the plurality of bent sheet portions, and a ground conductor that is provided in the first sheet portion, each bent sheet portion, and the second sheet portion and that is parallel to the plurality of signal lines.

The flexible substrate described in International Publication No. 2014/109135, which is a flexible substrate in which a bent sheet portion is provided in a bent portion, has an advantageous effect that isolation between different signals is improved.

However, because the bending line of the bent portion and the bending line of the bent sheet portion are parallel, the bent portion mechanically deforms easily. Therefore, depending on the use direction and use pattern, fatigue breakage of wiring in the bent portion may occur.

### SUMMARY OF THE INVENTION

Example embodiments of the present invention provide flexible multilayer substrates each including a bent portion with improved mechanical characteristics and/or electrical characteristics, cables each including a multilayer substrate, and electronic apparatuses each including a multilayer substrate.

A flexible multilayer substrate according to an example embodiment of the present invention includes a multilayer body including an insulator layer and a conductor layer stacked, wherein the multilayer body includes a bent portion and a bent-portion continuation portion continuous with the bent portion, and the multilayer body includes, in a portion of the bent portion, a protrusion protruding toward an inside of a bend of the bent portion.

A cable according to an example embodiment of the present invention includes a component mounted on the bent-portion continuation portion of a multilayer body of a flexible multilayer substrate, or a component mounted on a flat portion of a surface of the bent portion, wherein the component is a connector.

An electronic apparatus according to an example embodiment of the present invention includes a housing, wherein a multilayer substrate is in the housing.

With example embodiments of the present invention, flexible multilayer substrates each including a bent portion with improved mechanical characteristics and/or electrical characteristics, cables each including a multilayer substrate, and electronic apparatuses each including a multilayer substrate are obtained.

The above and other elements, features, steps, characteristics and advantages of the present invention will become more apparent from the following detailed description of the example embodiments with reference to the attached drawings.

### BRIEF DESCRIPTION OF THE DRAWINGS

FIGS. 1A and 1B are perspective views of a main portion of a multilayer substrate according to a first example embodiment of the present invention.

FIG. 2 illustrates a section of a central portion of a bent portion 1 of a multilayer body 4 of the multilayer substrate.

An upper portion of FIG. 3 is a sectional view of the bent portion 1 of the multilayer body 4 at a central portion along the width direction. A lower portion of FIG. 3 is a sectional view of the bent portion 1 of the multilayer body 4 at a central portion along the longitudinal direction.

FIG. 4 is a perspective view illustrating an example of the size relationship between the bent portion 1 and a protrusion 5 of the multilayer body 4.

FIGS. 5A to 5D illustrate some examples of the shape of a bent portion of the protrusion 5.

FIGS. 6A to 6C illustrate examples of a structure for mounting a component by using the protrusion.

FIG. 7 illustrates a multilayer substrate 102 according to an example embodiment of the present invention seen in a direction from a cut position of a flat portion (bent-portion continuation portion) thereof toward the protrusion 5.

FIG. 8 illustrates a multilayer substrate 102 according to an example embodiment of the present invention cut at a central portion of the protrusion 5 and seen at the cut position and toward the flat portion (bent-portion continuation portion) behind the cut position.

FIG. 9 illustrates sectional views illustrating the stack structure of insulator layers and conductor layers of the multilayer substrate 102.

FIG. 10 illustrates a multilayer substrate 103 according to an example embodiment of the present invention seen in a direction from a cut position of a flat portion (bent-portion continuation portion) thereof toward the protrusion 5.

FIG. 11 illustrates the multilayer substrate 103 cut at a central portion of the protrusion 5 and seen at the cut position and toward the flat portion (bent-portion continuation portion) behind the cut position.

FIG. 12 illustrates a multilayer substrate 104 according to an example embodiment of the present invention seen in a direction from a cut position of a flat portion (bent-portion continuation portion) thereof toward the protrusion 5.

FIG. 13 illustrates the multilayer substrate 104 cut at a central portion of the protrusion 5 and seen at the cut position and toward the flat portion (bent-portion continuation portion) behind the cut position.

FIG. 14 is a sectional view of a multilayer substrate 105 according to an example embodiment in a direction passing through a protrusion 5 of a multilayer body 4 along the longitudinal direction of the bent portion 1.

FIG. 15 is a perspective view of a multilayer substrate 106 according to an example embodiment of the present invention.

FIG. 16 illustrates a multilayer substrate 106 cut at a central portion of protrusions 5A and 5B and seen at the cut position and toward a flat portion (bent-portion continuation portion) behind the cut position.

FIG. 17 illustrates perspective views of a component-mounted multilayer substrate 107A according to an example embodiment of the present invention seen from two directions.

FIG. 18 illustrates a section of a central portion of the bent portion 1 of a multilayer body 4 of a multilayer substrate 107.

### DETAILED DESCRIPTION OF THE EXAMPLE EMBODIMENTS

Hereafter, example embodiments of the present invention will be described with reference to examples and the drawings. In the figures, the same portions are denoted by the same numerals. In consideration of ease of description or comprehension of main points, a plurality of example embodiments will be individually described for convenience of description of the example embodiments. However, it is possible to partially replace or combine configurations described in different example embodiments. In second to eighth example embodiments of the present invention, descriptions of matters common to those of a first example embodiment will be omitted, and only different points will be described. In particular, the same or similar advantageous effects due to similar configurations will not be described for each example embodiment.

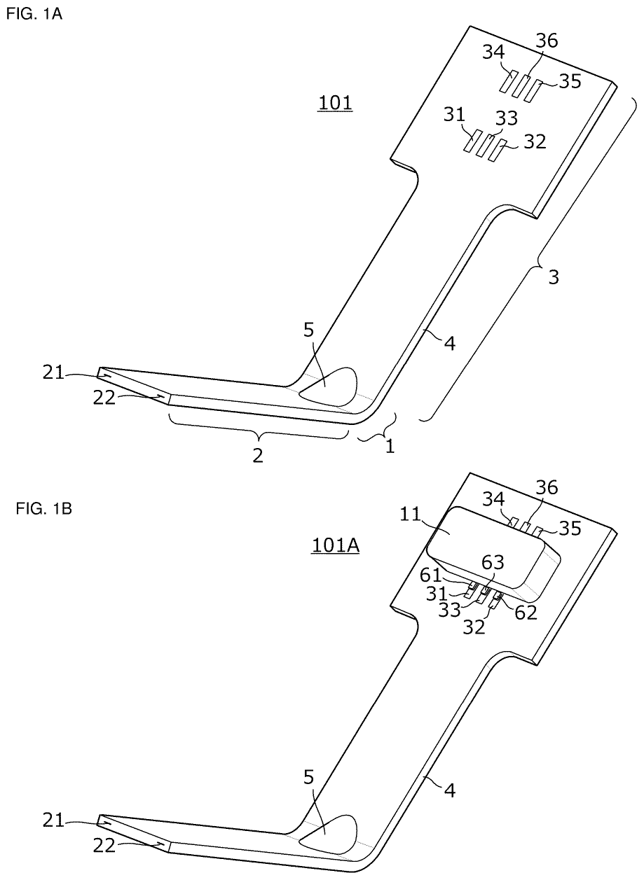

FIGS. 1A and 1B are perspective views of a main portion of a multilayer substrate according to a first example embodiment of the present invention. FIG. 1A is a perspective view of a multilayer substrate 101, and FIG. 1B is a perspective view of a main portion of a component-mounted multilayer substrate configured by mounting a component 11 on the multilayer substrate 101.

The multilayer substrate 101 includes a multilayer body 4 including layers of insulators and conductor films that are stacked. Detailed examples of the structure of the multilayer body 4 will be described below.

The multilayer body 4 includes a bent portion 1 and bent-portion continuation portions 2 and 3 that are continuous with the bent portion 1. Here, the term “bent-portion continuation portion” refers to a portion that is continuous with and extends from the bent portion 1. In the example embodiment illustrated in FIGS. 1A and 1B, the bent-portion continuation portions 2 and 3 each have a flat shape.

The multilayer body 4 includes, in a portion of the bent portion 1, a protrusion 5 that protrudes toward the inside of the bend of the bent portion 1. The protrusion 5 may be, for example, a rib or a bead.

In the example embodiment illustrated in FIGS. 1A and 1B, conductor layers 21 and 22 are provided in an inner layer of the multilayer body 4. Terminal electrodes 31, 32, 33, 34, 35, and 36 are exposed at a component mounting position near an end portion of the bent-portion continuation portion 3 that is flat.

In FIGS. 1A and 1B, a front portion of the multilayer substrate 101 is cut in order to show a main portion of the multilayer substrate 101. A portion of the multilayer substrate 101 illustrated in FIG. 1A where the conductor layers 21 and 22 are exposed is the cut portion of the multilayer substrate 101. A plurality of conductor layers are provided inside (in an inner layer) the multilayer body 4, and the conductor layers 21 and 22 are electrically connected to the terminal electrodes 31 and 32 via the conductor layers.

In the example embodiment illustrated in FIG. 1B, the component 11 includes six terminals, including terminals 61, 62, and 63, on a bottom surface portion thereof. The terminals 61, 62, and 63 are respectively soldered to the terminal electrodes 31, 32, and 33 of the multilayer substrate 101. Remaining three terminals are respectively soldered to the terminal electrodes 34, 35, and 36. All of the terminal electrodes 31 and 36 are not necessarily electrically connected to the conductor layers provided in the multilayer body 4, and there are cases where the terminal electrodes are used only to mount the component 11 on the multilayer substrate 101.

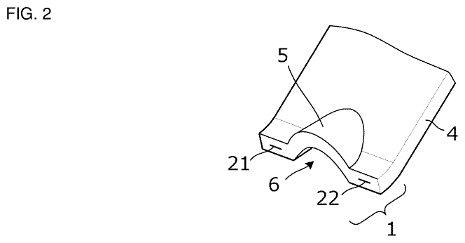

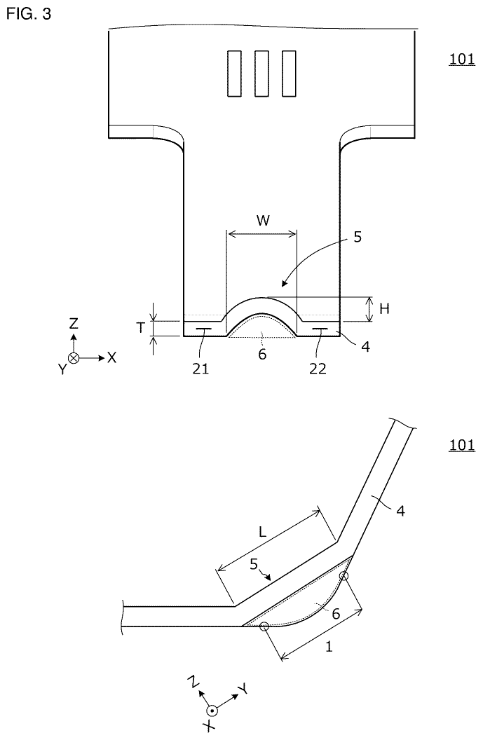

FIG. 2 illustrates a section of a central portion of the bent portion 1 of the multilayer body 4 of the multilayer substrate. The protrusion 5 is a portion of the bent portion 1 that protrudes toward the inside of the bend of the bent portion 1, and a hollow 6 is provided on the side opposite to the protruding direction of the protrusion 5. The conductor layers 21 and 22 are included inside (in an inner layer) of the multilayer body 4. In this way (in the present example embodiment), for example, the conductor layers 21 and 22 are signal-transmission conductor layers that extend in a direction passing beyond the bent portion 1. In this example embodiment, the signal-transmission conductor layers 21 and 22 are disposed at positions avoiding the protrusion 5. That is, the signal-transmission conductor layers 21 and 22 are provided so as to be routed through non-protruding positions in the multilayer body 4.

The upper portion of FIG. 3 is a sectional view of the bent portion 1 of the multilayer body 4 at a central portion along the width direction. The lower portion of FIG. 3 is a sectional view of the bent portion 1 of the multilayer body 4 at a central portion along the longitudinal direction.

The width W shown in the upper portion of FIG. 3 is the maximum dimension of the width of the hollow 6, which is on the opposite side to the protruding direction (the Z direction in FIG. 3) of the protrusion 5, along the extension direction (the X direction in FIG. 3) of a valley of the multilayer body 4 provided by bending of the multilayer body 4.

The height H shown in the upper portion of FIG. 3 is a protrusion height that is a dimension at which the protrusion protrudes highest.

The thickness T shown in the upper portion of FIG. 3 is the thickness dimension of the multilayer body 4 in a portion where the protrusion 5 is provided in the multilayer body 4.

The length L shown in the lower portion of FIG. 3 is a protrusion length that is the maximum length among lengths in a direction perpendicular or substantially perpendicular to the direction of the protrusion height H and the direction of the protrusion width W. The bent portion 1 of the multilayer body 4 illustrated in FIG. 3 is a portion between the boundaries between curved surfaces and flat surfaces inside of the bend of the bent portion 1 of the multilayer body 4.

In the example embodiment illustrated in FIG. 3, each of the protrusion width W, the protrusion height H, and the protrusion length L is greater than or equal to the thickness T of the multilayer body 4.

At least one of the protrusion width W, the protrusion height H, and the protrusion length L may be greater than or equal to the thickness T of the multilayer body 4. In this case, the multilayer substrate 101 or a component-mounted multilayer substrate 101A including the bent portion 1 with improved mechanical characteristics such as rigidity is obtained.

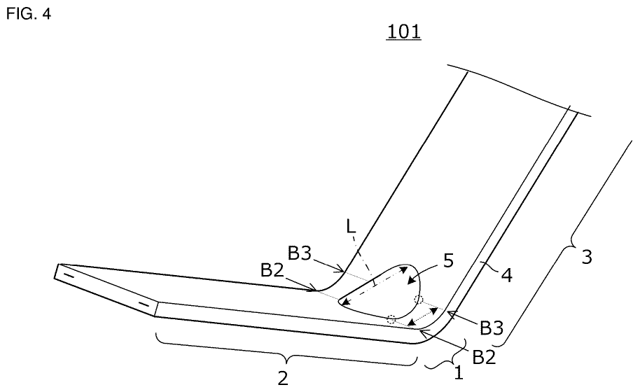

FIG. 4 is a perspective view illustrating an example of the size relationship between the bent portion 1 and the protrusion 5 of the multilayer body 4. In the example embodiment illustrated in the FIG. 4, a portion of the protrusion 5 extends beyond the boundaries B2 and B3 between the bent portion 1 and the bent-portion continuation portions 2 and 3 in directions toward the bent-portion continuation portions 2 and 3. Two circular marks in FIG. 4 indicate the positions from which the protrusion 5 starts to extend beyond the boundaries. In other words, the length L of the protrusion 5 illustrated in FIG. 4 is greater than the length of the bent portion 1 (the distance between the bent-portion continuation portion 2 and the bent-portion continuation portion 3). With this structure, the advantageous effect of increasing the rigidity of the bent portion is increased.

With the present example embodiment, the multilayer substrate 101 including the bent portion 1 with improved mechanical characteristics such as rigidity is obtained. Moreover, by mounting the component 11 on the multilayer substrate 101, the component-mounted multilayer substrate 101A including the bent portion 1 with improved mechanical characteristics such as rigidity is obtained.

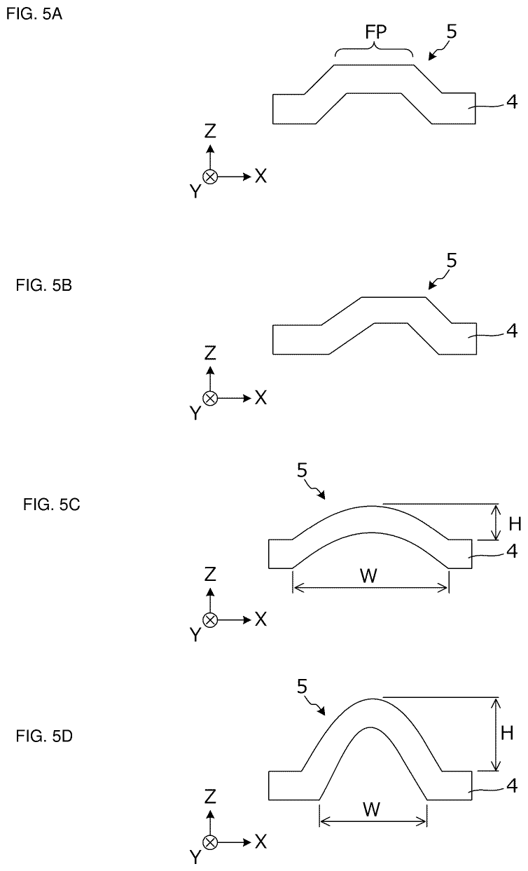

FIGS. 5A to 5D illustrate some examples of the shape of a bent portion of the protrusion 5. Here, a section passing through the center of the protrusion 5 (a section along the extension direction (the X direction) of the valley of the multilayer body 4 formed by bending of the multilayer body 4) is illustrated.

In the example embodiment illustrated in FIG. 5A, the protrusion 5 includes a flat portion FP at a top thereof. In this way, the top of the protrusion 5 need not be a curved surface.

In the example embodiment illustrated in FIG. 5B, the protrusion 5 is asymmetrical in the section. In this way, the shape of the protrusion 5 may be asymmetrical in a plane perpendicular or substantially perpendicular to the longitudinal direction of the protrusion 5. Thus, it is also possible to intentionally make the rigidity characteristics of the bent portion asymmetrical. Moreover, when a conductor layer (not shown in FIGS. 5A to 5D) is to be disposed in the multilayer body 4 in accordance with electrical characteristics, it is easy to dispose the conductor layer asymmetrically.

In the example embodiment illustrated in FIG. 5C, the ratio of the width W of the protrusion 5 to the height H of the protrusion 5 is greater than those of the example embodiments illustrated in FIG. 2, FIG. 3, and other figures. With this structure, because the height of the protrusion 5 is small, the volume of the protrusion is small when the bending angle of the bent-portion continuation portions 2 and 3 (see FIGS. 1A and 1B) at the bent portion 1 is small, and space saving can be achieved.

In the example embodiment illustrated FIG. 5D, the width W and the height H of the protrusion 5 are equal or approximately equal or the ratio of the height H to the width W is greater than those of the examples illustrated in FIG. 2, FIG. 3, and other figures. With this structure, it is possible to easily increase the rigidity of the bent portion. As described below by using examples, shielding and isolation between signal-transmission conductor layers, which are disposed at positions avoiding the protrusion, can be easily increased.

As described above by using example embodiments, it is possible to determine the shape, the width, and the height of the protrusion 5 as appropriate.

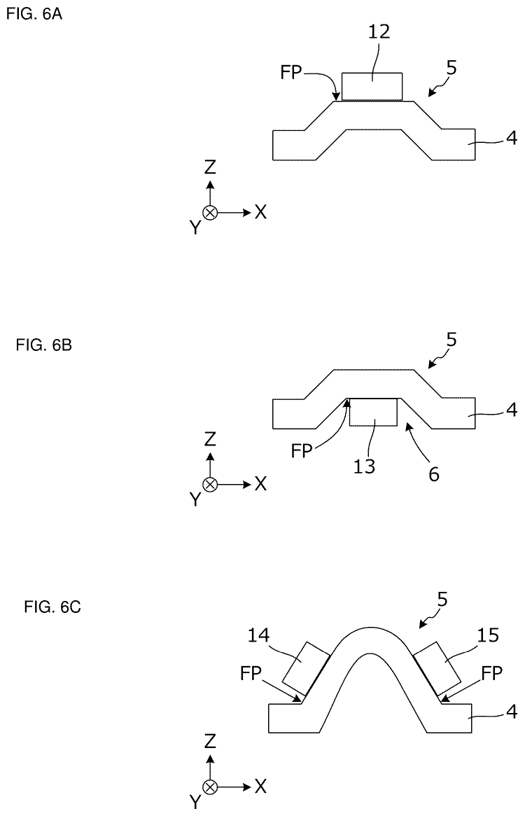

FIGS. 6A to 6C illustrate examples of a structure for mounting a component by using the protrusion. Here, a section passing through the center of the protrusion 5 (a section cut in the extension direction (the X direction) of the valley of the multilayer body 4 provided by bending of the multilayer body 4) is illustrated.

In the example embodiment illustrated in FIG. 6A, the protrusion 5 includes the flat portion FP in an outer surface thereof, and a component 12 is mounted on the flat portion FP. With this structure, it is possible to provide the component 12 without using a surface of the bent-portion continuation portion such as the flat portion of the multilayer body 4. Moreover, electrical influence on a conductor layer disposed in the bent-portion continuation portion such as the flat portion of the multilayer body 4 can be reduced or prevented. Furthermore, as described below by using examples, it is possible to easily perform connection and coupling with a transmission line passing through the protrusion 5.

In the example embodiment illustrated in FIG. 6B, the protrusion 5 includes the flat portion FP in an inner surface thereof, and a component 13 is mounted on the flat portion FP. With this structure, advantageous effects the same as or similar to those of the example embodiment illustrated in FIG. 6A can be obtained. Moreover, it is possible to effectively use the overall space, because the component 13 is mounted in the hollow 6.

In the example embodiment illustrated in FIG. 6C, the protrusion 5 includes the flat portions FP in an outer surface thereof. Components 14 and 15 are mounted on the flat portions FP. With this structure, advantageous effects the same as or similar to those of the example embodiment illustrated in FIG. 6A can be obtained. Moreover, it is possible to effectively use the overall space, because the components 14 and 15 are mounted in the height range of the protrusion 5.

The component 11 of the component-mounted multilayer substrate 101A described in the first example embodiment is, for example, a connector. That is, the connector of the component-mounted multilayer substrate 101A is connected to a connector of another circuit substrate. It is possible to use the component-mounted multilayer substrate 101A as a cable.

In FIGS. 1A and 1B, the component 11 is mounted at one end of the multilayer body 4, and illustration of the other end is omitted. However, a component may be mounted also at the other end. The other end may be directly connected to another circuit substrate.

In a second example embodiment of the present invention, a multilayer substrate 102 in which the multilayer body 4 includes a signal-transmission conductor layer will be described as an example.

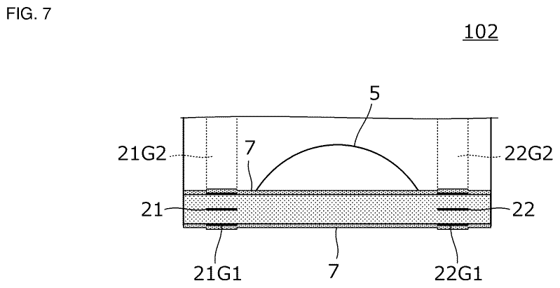

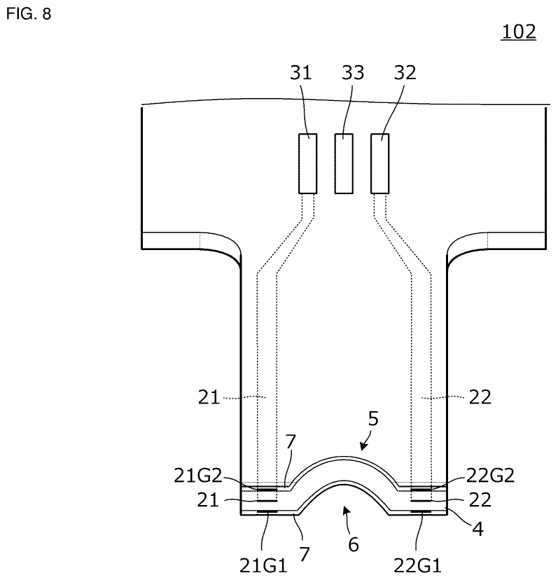

FIG. 7 illustrates the multilayer substrate 102 seen in a direction from a cut position of a flat portion (bent-portion continuation portion) thereof toward the protrusion 5. FIG. 8 illustrates the multilayer substrate 102 cut at a central portion of the protrusion 5 and seen at the cut position and toward the flat portion (bent-portion continuation portion) behind the cut position.

The multilayer substrate 102 according to the second example embodiment includes, in the multilayer body 4, signal-transmission conductor layers that extend in a direction beyond the bent portion. As illustrated in FIGS. 7 and 8, conductor layers 21, 21G1, and 21G2 and conductor layers 22, 22G1, and 22G2 are provided in the multilayer body 4. Each of these conductor layers extends in the direction of the bent-portion continuation portion (flat portion) 2, the bent portion 1, and the bent-portion continuation portion (flat portion) 3 illustrated in FIGS. 1A and 1B in the first example embodiment.

The conductor layer 21 is a signal line layer, the conductor layer 21G1 is a lower ground wiring layer, and the conductor layer 21G2 is an upper ground wiring layer. These conductor layers 21, 21G1, and 21G2 define a first strip line.

The conductor layer 22 is a signal line layer, the conductor layer 22G1 is a lower ground wiring layer, and the conductor layer 22G2 is an upper ground wiring layer. These conductor layers 22, 22G1, and 22G2 define a second strip line.

As illustrated in FIGS. 7 and 8, a protective film 7 that is electrically insulating is provided on each of the upper and lower surfaces of the multilayer body 4.

FIG. 8 illustrates a pattern between the conductor layers 21 and 22, each of which defines a signal line layer, and the terminal electrodes 31 and 32. In the first strip line defined by the conductor layers 21, 21G1, and 21G2, the conductor layer 21 is connected to the terminal electrode 31. Similarly, in the second strip line defined by the conductor layers 22, 22G1, and 22G2, the conductor layer 22 is connected to the terminal electrode 32. The hollow 6 is provided on the opposite side to the protrusion 5.

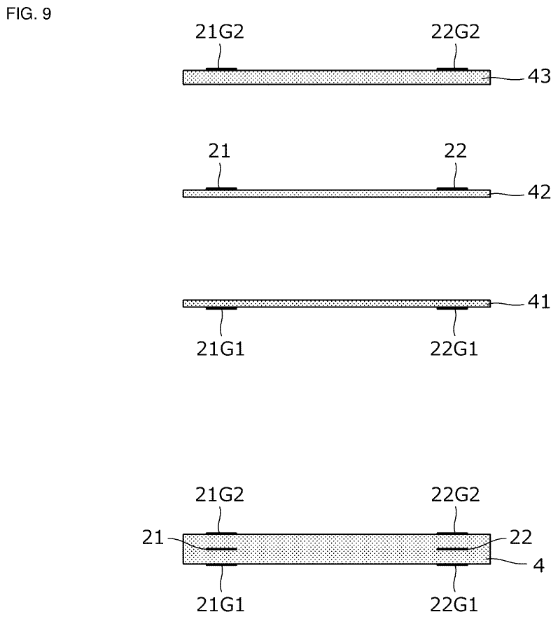

FIG. 9 illustrates sectional views illustrating the stack structure of insulator layers and conductor layers of the multilayer substrate 102. The upper portion of FIG. 9 illustrates the insulator layers and the conductor layers before being formed into a multilayer body, and the lower portion of FIG. 9 illustrates the multilayer body 4 that has been formed.

An example of a process of manufacturing the multilayer substrate 102 according to an example embodiment of the present invention is as follows.
(1) In the orientation illustrated in the upper portion of FIG. 9, the conductor layers 21G1 and 22G1 as ground conductor layers are formed on the lower surface of an insulator layer 41. The signal-transmission conductor layers 21 and 22 are formed on the upper surface of an insulator layer 42. The conductor layers 21G2 and 22G2 as ground conductor layers are formed on the upper surface of an insulator layer 43. The material of the insulator layers 41, 42, and 43 is, for example, LCP (liquid crystal polymer). The conductor layers 21G1, 21, 21G2, 22G1, 22, and 22G2 are, for example, Cu films or Al films. These conductor layers are formed by being affixed to the entire or substantially the entire surfaces of the insulator layers and patterned.
(2) The multilayer body 4 illustrated in the lower portion of FIG. 9 is formed by stacking the insulator layers, on which the conductor layers have been patterned, and by heating and pressing the insulator layers.
(3) Subsequently, as illustrated in FIGS. 7 and 8 and other figures, the upper and lower surfaces of the multilayer body 4 are covered with the protective films 7. The material of the protective films 7 is, for example, PI (polyimide).
(4) The bent portion 1 is formed by bending a predetermined portion of the multilayer body 4, covered with the protective films 7, by using, for example, a jig while heating the multilayer body 4. The protrusion 5 is formed at the same time as bending the multilayer body 4 by using the jig. The protrusion 5 may be formed by, for example, punching the bent portion from the outside of the bent portion after a predetermined portion of the multilayer body 4 has been bent by using the jig. However, by forming the protrusion 5 at the same time as bending the multilayer body 4, it is possible to reduce or prevent abnormal deformation and deterioration of insulator layers and conductor layers.

With the present example embodiment, because the mechanical rigidity of the bent portion 1 is high, the distance between the bent-portion continuation portion 2 and the bent-portion continuation portion 3, which are continuous with the bent portion 1, is stabilized. Thus, extension, contraction, and vibration (for example, spring back) of a signal-transmission conductor layer are reduced or prevented, and variation in the electrical resistance of the conductor layer is reduced or prevented. Moreover, variation in the electrical resistance due to heat generated by friction between an insulator layer and a conductor layer is reduced or prevented. As a result of these, electrical noise relative to an electric signal to be transmitted is reduced or prevented. Moreover, because the distance between a conductor layer formed in the bent-portion continuation portion 2 and a conductor layer formed in the bent-portion continuation portion 3 is stabilized, variation in the capacitance between the conductor layer formed in the bent-portion continuation portion 2 and the conductor layer formed in the bent-portion continuation portion 3 is reduced or prevented. Thus, electrical noise relative to an electrical signal to be transmitted is reduced or prevented. Moreover, variation in the distance between a signal-transmission conductor layer and a ground conductor layer in the bent portion is reduced or prevented. Thus, electrical noise relative to an electrical signal to be transmitted is reduced or prevented.

By forming the conductor layer 21G1 and the conductor layer 22G1 from a continuous conductor layer, it is possible to increase isolation between the first strip line and the second strip line.

Because the hollow 6 is on both sides of the protrusion 5 (left and right in FIG. 8 and other figures), it is possible to increase isolation between the first strip line and the second strip line due to the function of the dielectric loss of this low-permittivity dielectric.

In a third example embodiment of the present invention, a multilayer substrate in which a protrusion includes a conductor layer to increase rigidity will be described as an example.

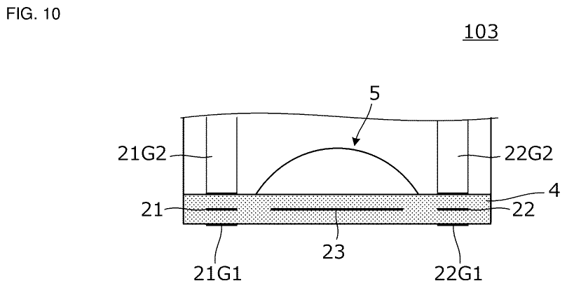

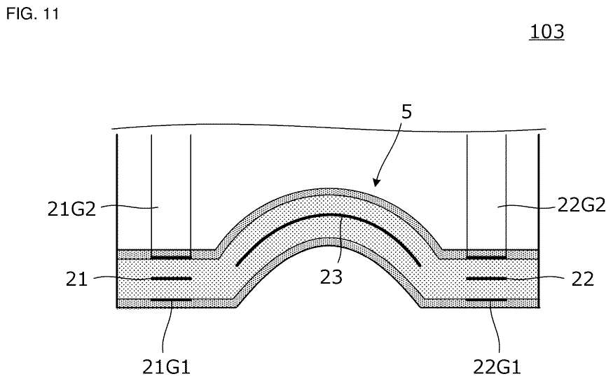

FIG. 10 illustrates a multilayer substrate 103 seen in a direction from a cut position of a flat portion (bent-portion continuation portion) thereof toward the protrusion 5. FIG. 11 illustrates the multilayer substrate 103 cut at a central portion of the protrusion 5 and seen at the cut position and toward the flat portion (bent-portion continuation portion) behind the cut position.

The conductor layer 21 is a signal line layer, the conductor layer 21G1 is a lower ground wiring layer, and the conductor layer 21G2 is an upper ground wiring layer. These conductor layers 21, 21G1, and 21G2 define a first strip line.

The conductor layer 22 is a signal line layer, the conductor layer 22G1 is a lower ground wiring layer, and the conductor layer 22G2 is an upper ground wiring layer. These conductor layers 22, 22G1, and 22G2 define a second strip line.

The multilayer substrate 103 according to the third example embodiment includes conductor layers inside (in an inner layer) of the protrusion 5 of the multilayer body 4. In the present example embodiment, a conductor layer 23 is arranged not only inside (in an inner layer) of the protrusion 5 but also between the two strip lines. The conductor layer 23 may be used as a signal-transmission conductor that is different from the first strip line and the second strip line.

With the present example embodiment, because a conductor layer is included inside (in an inner layer) of the protrusion, the rigidity of the protrusion 5 is increased, and it is possible to further improve the mechanical characteristics, such as the rigidity, of the bent portion 1 including the protrusion 5.

In a fourth example embodiment of the present invention, a multilayer substrate 104 including a signal-transmission conductor layer in the protrusion 5 will be described as an example.

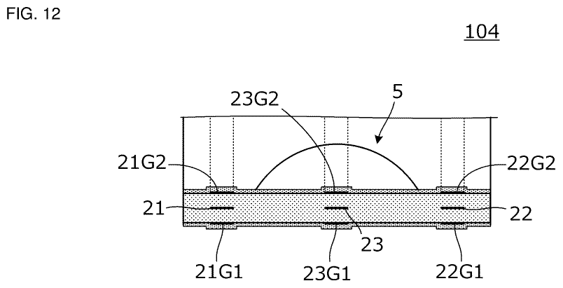

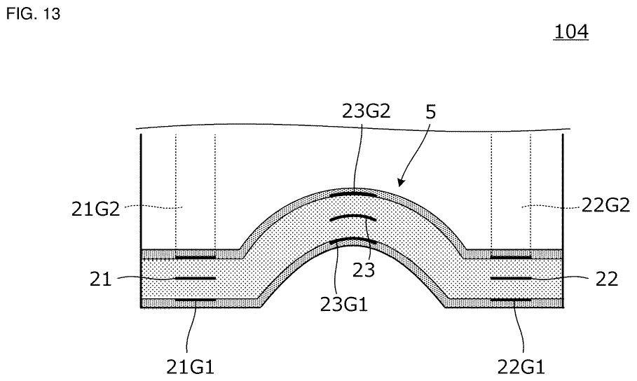

FIG. 12 illustrates the multilayer substrate 104 seen in a direction from a cut position of a flat portion (bent-portion continuation portion) thereof toward the protrusion 5. FIG. 13 illustrates the multilayer substrate 104 that is cut at a central portion of the protrusion 5 and seen at the cut position and toward the flat portion (bent-portion continuation portion) behind the cut position.

The conductor layer 21 is a signal line layer, the conductor layer 21G1 is a lower ground wiring layer, and the conductor layer 21G2 is an upper ground wiring layer. These conductor layers 21, 21G1, and 21G2 define a first strip line.

The conductor layer 22 is a signal line layer, the conductor layer 22G1 is a lower ground wiring layer, and the conductor layer 22G2 is an upper ground wiring layer. These conductor layers 22, 22G1, and 22G2 define a second strip line.

The conductor layer 23 is a signal line layer, a conductor layer 23G1 is a lower ground wiring layer, and a conductor layer 23G2 is an upper ground wiring layer. These conductor layers 23, 23G1, and 23G2 define a third strip line. The third strip line passes through the protrusion 5.

With the present example embodiment, because a signal-transmission conductor layer is provided without avoiding the position of the protrusion 5, the number of signal transmission lines per width in a direction perpendicular or substantially perpendicular to the signal transmission direction can be increased.

Moreover, because the line length of the entirety of a signal transmission line passing through the protrusion 5 can be reduced, it is possible to reduce transmission signal loss.

In a fifth example embodiment of the present invention, a multilayer substrate including a conductor layer including an interlayer connection conductor will be described as an example.

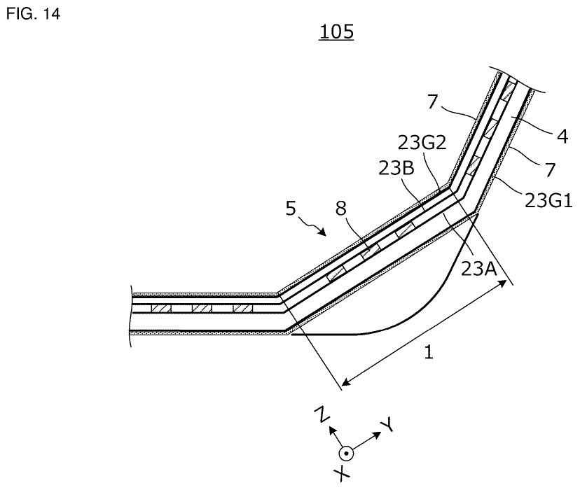

FIG. 14 is a sectional view of a multilayer substrate 105 according to a fifth example embodiment in a direction passing through the protrusion 5 of the multilayer body 4 along the longitudinal direction of the bent portion 1.

Conductor layers 23A and 23B are interlayer-connected by a plurality of interlayer connection conductors 8. The conductor layer 23G1 is a lower ground wiring layer, and the conductor layer 23G2 is an upper ground wiring layer. The conductor layers 23A and 23B, the interlayer connection conductors 8, the conductor layer 23G1, and the conductor layer 23G2 define a strip line that passes through an inner layer of the protrusion 5.

In this way, by configuring the signal-transmission conductor layer from a plurality of conductor layers and interlayer connection conductors that interlayer-connect the conductor layers, it is possible to increase electric conductivity and to reduce transmission signal loss.

With existing structures that do not include the protrusion 5, it is difficult to provide an interlayer connection conductor in a curved bent portion thereof. However, with the present example embodiment, because the protrusion 5 includes a flat region, it is possible to easily provide an interlayer connection conductor in the flat region.

Also regarding a strip line that does not pass through the protrusion 5, a signal-transmission conductor layer may be defined by a plurality of conductor layers and an interlayer connection conductor that interlayer-connects the conductor layers.

In a sixth example embodiment of the present invention, a multilayer substrate in which the number of protrusions provided at a bent portion is plural will be described as an example.

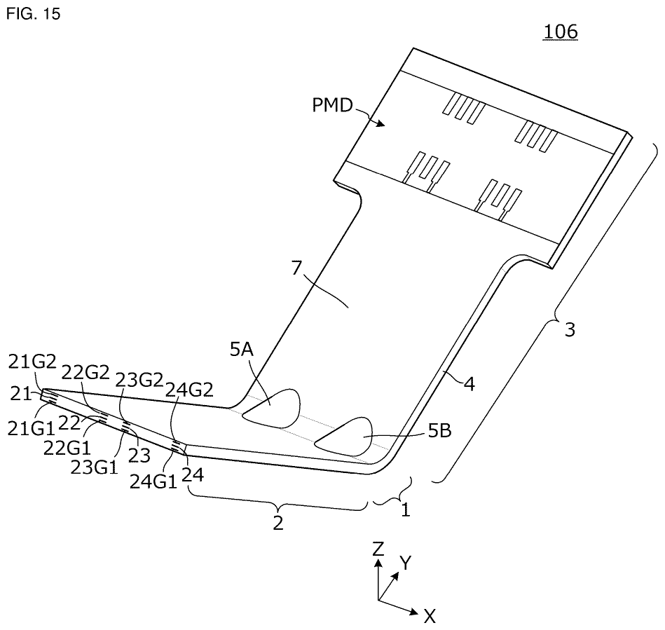

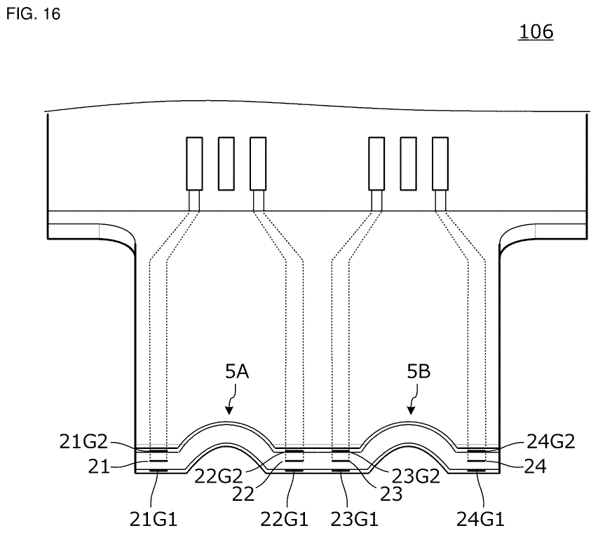

FIG. 15 is a perspective view of a multilayer substrate 106 according to the present example embodiment. FIG. 16 illustrates the multilayer substrate 106 cut at a central portion of protrusions 5A and 5B and seen at the cut position and toward a flat portion (bent-portion continuation portion) behind the cut position.

The multilayer body 4 includes the bent portion 1 and the bent-portion continuation portions 2 and 3 that are continuous with the bent portion 1. Here, in the example embodiment illustrated in FIG. 15, the bent-portion continuation portions 2 and 3 each have a flat shape. The multilayer body 4 includes, in two portions of the bent portion 1, the protrusions 5A and 5B that protrude toward the inside of the bend of the bent portion 1.

In the multilayer body 4, conductor layers 21, 21G1, 21G2, 22, 22G1, 22G2, 23, 23G1, 23G2, 24, 24G1, and 24G2 are provided. Moreover, in the multilayer body 4, a component mounting portion PMD is provided.

The conductor layers 21, 21G1, and 21G2 define a first strip line. The conductor layers 22, 22G1, and 22G2 define a second strip line. Likewise, the conductor layers 23, 23G1, and 23G2 define a third strip line, and the conductor layers 24, 24G1, and 24G2 define a fourth strip line.

With the present example embodiment, because the plurality of protrusions 5A and 5B are provided in the extension direction (the X direction) of the valley of the multilayer body formed by bending the multilayer body 4 in order to form the bent portion 1, it is possible to obtain the multilayer substrate 106 including the bent portion 1 with high rigidity even though the valley of the multilayer body is long in the extension direction. Moreover, freedom in the location of a conductor layer as a transmission line is increased by setting of the positions of the plurality of protrusions 5A and 5B.

Although two protrusions 5A and 5B are provided in the example embodiment illustrated in FIGS. 15 and 16, three or more protrusions may be provided in the same way. As with the example described in the fourth example embodiment, a signal line conductor may be provided on a surface or in an inner layer of the protrusions 5A and 5B.

Regarding the protrusions 5A and 5B, various types of protrusions 5A and 5B that differ in sizes (width, height, and length) thereof may be provided.

In a seventh example embodiment of the present invention, a multilayer substrate including a conductor layer on an upper surface or in an inner layer of the protrusion 5 will be described as an example.

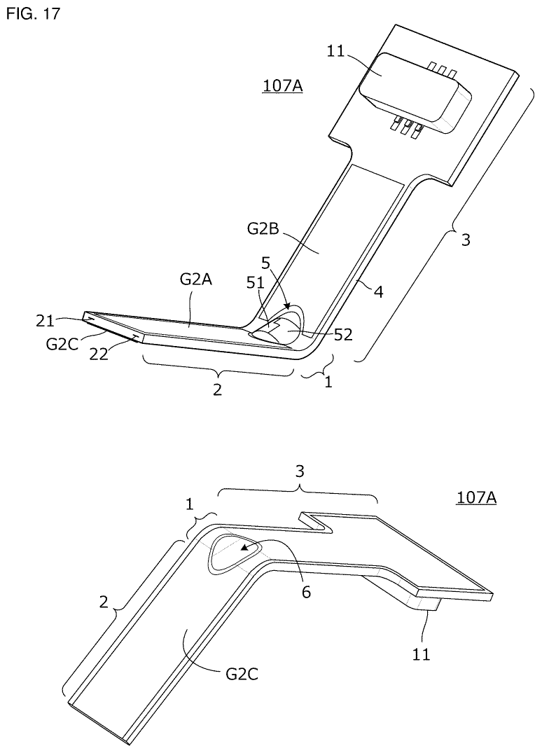

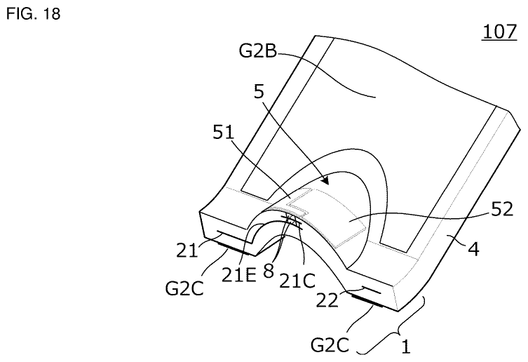

FIG. 17 illustrates perspective views of a component-mounted multilayer substrate 107A according to the present example embodiment seen from two directions. The upper portion of FIG. 17 is a perspective view in a direction in which the protrusion 5 of the multilayer substrate of the component-mounted multilayer substrate 107A can be seen, and the lower portion of FIG. 17 is a perspective view in a direction in which the hollow 6 of the multilayer substrate of the component-mounted multilayer substrate 107A can be seen. FIG. 18 illustrates a section of a central portion of the bent portion 1 of the multilayer body 4 of the multilayer substrate 107.

The multilayer body 4 includes the bent portion 1 and the bent-portion continuation portions 2 and 3 that are continuous with the bent portion 1. The multilayer body 4 includes, in a portion of the bent portion 1, the protrusion 5 that protrudes toward the inside of the bend of the bent portion 1.

A ground conductor G2A is provided on an upper surface of the bent-portion continuation portion 2 that is flat, and a ground conductor G2B is provided on an upper surface of the bent-portion continuation portion 3 that is flat.

As illustrated in FIGS. 17 and 18, the ground conductor G2A is provided on an upper surface of the bent-portion continuation portion 2 of the multilayer body 4, and the ground conductor G2B is provided on an upper surface of the bent-portion continuation portion 3. A ground conductor G2C is provided on lower surfaces of the bent-portion continuation portion 2, the bent portion 1, and the bent-portion continuation portion 3. The signal-transmission conductor layers 21 and 22 are provided in an inner layer.

With the configuration described above, the signal-transmission conductor layer 21, the ground conductor G2C, and the ground conductor G2A define a first strip line. Similarly, the signal-transmission conductor layer 22, the ground conductor G2C, and the ground conductor G2A define a second strip line.

The signal-transmission conductor layer 21 is led out to an upper portion of the protrusion 5 via a lead-out conductor layer 21E in an inner layer of the protrusion 5. A radiating element 51 is provided on an upper surface of the protrusion 5. The lead-out conductor layer 21E is connected to a feeding point of the radiating element 51 via an interlayer electrode 21C and the interlayer connection conductor 8.

Similarly, the signal-transmission conductor layer 22 is led out to an upper portion of the protrusion 5 via a lead-out conductor layer in an inner layer of the protrusion 5. A radiating element 52 is provided on an upper surface of the protrusion 5. A lead-out conductor layer is connected to a feeding point of the radiating element 52 via an interlayer electrode and an interlayer connection conductor. At the sectional position illustrated in FIG. 18, the lead-out conductor layer, the interlayer electrode, and the interlayer connection conductor that are electrically connected to the radiating element 52 are not illustrated.

As illustrated in the lower portion of FIG. 17, the ground conductor G2C, which is provided on the lower surfaces of the bent-portion continuation portion 2, the bent portion 1, and the bent-portion continuation portion 3, is widely provided at a position excluding the hollow 6 (position that does not face the radiating elements 51 and 52). The ground conductor G2C and the ground conductor G2A are electrically connected via an interlayer connection conductor. Similarly, the ground conductor G2C and the ground conductor G2B are electrically connected via an interlayer connection conductor. These interlayer connection conductors are arranged at a predetermined interval between the signal-transmission conductor layer 21 and the signal-transmission conductor layer 22 and in the longitudinal direction of the bent portion (direction in which the bent-portion continuation portion 2, the bent portion 1, and the bent-portion continuation portion 3 are continuous).

The radiating element 51 defines and functions as a first patch antenna, and an antenna signal is input via the first strip line. Similarly, the radiating element 52 defines and functions as a second patch antenna, and an antenna signal is input via the second strip line.

With the present example embodiment, because the radiating elements 51 and 52 and the like can be provided in such a way as to straddle the protrusion 5, a plurality of radiating elements can be easily provided. Moreover, because the orientations of the radiating elements 51 and 52 are different, a plurality of antennae having different directivities can be configured. Accordingly, it is possible to use the radiating elements as an antenna having wide directivity.

In the lower portion of FIG. 17, an example in which a ground conductor is not provided on the inner surface of the hollow 6 is illustrated. However, a surface of a ground conductor facing the radiating elements 51 and 52 may be provided by forming a ground conductor on the inner surface of the hollow 6. Thus, for example, an influence of variation in antenna characteristics due to another conductor adjacent to the radiating elements 51 and 52 can be reduced or prevented.

For example, when the protrusion 5 is asymmetrical in a section thereof as in the example illustrated in FIG. 5B, it is also possible to make the directivity of the antenna asymmetrical.

In the example embodiment illustrated in FIGS. 17 and 18, the radiating elements 51 and 52 having the same or substantially the same shape are disposed symmetrically with respect to rotation of 180 degrees. However, for example, a plurality of radiating elements having different sizes and thus having different frequency characteristics may be provided. Thus, an antenna used for a plurality of frequency bands can be configured.

In the example embodiment illustrated in FIGS. 17 and 18, two antennae are provided on the protrusion 5. However, a single antenna may be provided.

In the example embodiment illustrated in FIGS. 17 and 18, the radiating elements 51 and 52 are provided on a surface of the protrusion 5. However, a radiating element may be provided in an inner layer.

Moreover, a conductor layer provided in the protrusion 5 is not limited to a radiating element, and may be a conductor layer defining and functioning as a capacitor, an inductor, or the like.

In an eighth example embodiment of the present invention, an electronic apparatus will be described as an example. The electronic apparatus includes a housing to accommodate various substrates and members. A circuit substrate, for example, is accommodated in the housing, and a multilayer substrate according to each of the example embodiments described above is disposed in the housing.

With the present example embodiment, an electronic apparatus having a high mechanical strength against vibration can be provided. Moreover, an electronic apparatus that has high electrical stability against vibration and with which noise generation is reduced or prevented can be provided.

Lastly, the present invention is not limited to the example embodiments described above. It is possible for a person having ordinary skill in the art to modify and change the example embodiments as appropriate. The scope of the present invention is not defined by the example embodiments described above but is defined by the claims. Moreover, modifications and changes from the example embodiments that are within the claims and the equivalents thereof are included in the scope of the present invention.

For example, in the example embodiments described above, examples in which a bent-portion continuation portion that continuously extends from a bent portion of a multilayer body has a flat shape have been described. However, the bent-portion continuation portion may be curved, for example. Because a region excluding the bent portion is flexible, it is easy to incorporate the multilayer substrate in a housing in an electronic apparatus.

A component to be mounted on a multilayer substrate may be, for example, instead of a connector, a chip component such as a microphone, an IC, a chip capacitor, or a chip inductor.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multilayer substrate comprising:
a multilayer body including an insulator layer and a conductor layer that are stacked; wherein
the multilayer body includes a bent portion and a bent-portion continuation portion continuous with the bent portion; and
the multilayer body includes, in a portion of the bent portion, a protrusion protruding toward an inside of a bend of the bent portion.

2. The multilayer substrate according to claim 1, wherein
a portion of the conductor layer on a surface of the protrusion or in an inner layer of the protrusion includes a plurality of layers; and
the multilayer substrate includes an interlayer connection conductor electrically interlayer-connecting the plurality of layers of the conductor layer.

3. The multilayer substrate according to claim 1, wherein a portion of the conductor layer defines a signal-transmission conductor layer extending in a direction passing beyond the bent portion.

4. The multilayer substrate according to claim 3, wherein at least a portion of the signal-transmission conductor layer is located at a position passing through the protrusion.

5. The multilayer substrate according to claim 3, wherein at least a portion of the signal-transmission conductor layer is located at a position avoiding the protrusion.

6. The multilayer substrate according to claim 1, further comprising a protective film on a surface of the multilayer body.

7. The multilayer substrate according to claim 1, wherein
at least one of a protrusion width, a protrusion height, and a protrusion length is greater than or equal to a thickness of the multilayer body;
the protrusion width is a maximum dimension of a width of a hollow, which is on an opposite side of a protruding direction of the protrusion, along an extension direction of a valley of the multilayer body provided by bending of the multilayer body;
the protrusion height is a dimension by which the protrusion protrudes highest; and
the protrusion length is a maximum length among lengths in a direction perpendicular or substantially perpendicular to a direction of the protrusion height and a direction of the protrusion width.

8. The multilayer substrate according to claim 1, wherein
each of a protrusion width, a protrusion height, and a protrusion length is greater than or equal to a thickness of the multilayer body;
the protrusion width is a maximum dimension of a width of a hollow, which is on an opposite side of a protruding direction of the protrusion, along an extension direction of a valley of the multilayer body provided by bending of the multilayer body;
the protrusion height is a dimension by which the protrusion protrudes highest; and
the protrusion length is a maximum length among lengths in a direction perpendicular or substantially perpendicular to a direction of the protrusion height and a direction of the protrusion width.

9. The multilayer substrate according to claim 1, wherein a portion of the protrusion extends beyond a boundary between the bent portion and the bent-portion continuation portion in a direction toward the bent-portion continuation portion.

10. The multilayer substrate according to claim 1, wherein the protrusion includes a plurality of protrusions.

11. The multilayer substrate according to claim 1, wherein the multilayer body includes a radiator at a position including a surface of the protrusion or a surface-layer portion of the protrusion portion.

12. The multilayer substrate according to claim 1, wherein a material of the insulator layer includes a thermoplastic resin.

13. The multilayer substrate according to claim 1, further comprising a component mounted on the bent-portion continuation portion.

14. The multilayer substrate according to claim 1, wherein
the bent portion includes a flat portion on a surface of the bent portion; and
the multilayer substrate includes a component mounted on the flat portion.

15. A cable comprising:
the multilayer substrate according to claim 13, wherein
the component is a connector.

16. An electronic apparatus comprising:
a housing; wherein
the multilayer substrate according to claim 1 is in the housing.

17. The electronic apparatus according to claim 16, wherein
a portion of the conductor layer on a surface of the protrusion or in an inner layer of the protrusion includes a plurality of layers; and
the multilayer substrate includes an interlayer connection conductor electrically interlayer-connecting the plurality of layers of the conductor layer.

18. The electronic apparatus according to claim 16, wherein a portion of the conductor layer defines a signal-transmission conductor layer extending in a direction passing beyond the bent portion.

19. An electronic apparatus comprising:
a housing; wherein
the cable according to claim 15 is in the housing.

20. The electronic apparatus according to claim 16, wherein
a portion of the conductor layer on a surface of the protrusion or in an inner layer of the protrusion includes a plurality of layers; and
the multilayer substrate includes an interlayer connection conductor electrically interlayer-connecting the plurality of layers of the conductor layer.
